(19) United States
(12) Patent Application Publication
(10) Pub. No.: US 2008/0069954 A1
(43) Pub. Date: Mar. 20, 2008

(54) METHOD AND APPARATUS FOR DISPENSE OF CHEMICAL VAPOR IN A TRACK LITHOGRAPHY TOOL

(75) Inventor: Y. Sean Lin, Irvine, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SOKUDO CO., LTD., Kyoto (JP)

(21) Appl. No.: 11/693,642

(22) Filed: Mar. 29, 2007

Related U.S. Application Data
(60) Provisional application No. 60/821,918, filed on Aug. 9, 2006.

(51) Int. Cl. C23C 16/00

(52) U.S. Cl. 427/255.28; 118/715

(57) ABSTRACT

A buffer vessel and a vapor tube in a track tool are configured as a diffusion vaporizer to deliver a flow of photolithography chemical vapor to a chamber for coating a wafer. Pressure in the buffer vessel is equalized to eliminate negative pressure in the buffer vessel. The size of the buffer vessel is selected such that a volume of photolithography chemical vapor that is sufficient to coat an entire lot of wafers is provided to the chamber when there is no longer any photolithography chemical in a source bottle.

### CROSS-REFERENCES TO RELATED APPLICATIONS

The present application claims benefit under 35 U.S.C. § 119(e) of U.S. Provisional Patent Application No. 60/821,918, filed Aug. 9, 2006, entitled “Photolithography Chemical Vapor Dispense System for a Track Tool,” which is incorporated herein by reference in its entirety.

### BACKGROUND OF THE INVENTION

The present invention relates generally to the field of substrate processing equipment. More particularly, the present invention relates to the delivery of photolithography chemical vapor in a track tool. Merely by way of example, the method and apparatus of the present invention are used to deliver photolithography chemical vapor in a track tool using a diffusion vaporizer. The method and apparatus can be applied to other processes for semiconductor substrates, for example those used in the formation of integrated circuits.

Modern integrated circuits contain millions of individual elements that are formed by patterning the materials making up the integrated circuit to sizes that are small fractions of a micrometer. A technique typically used throughout the industry for forming such patterns is photolithography. A photolithography process sequence generally includes the deposition of one or more uniform photoresist (resist) layers on the surface of a substrate, followed by the drying and curing of the deposited layers, patterning of the substrate by exposing the photoresist layer to electromagnetic radiation suitable for modifying the exposed layer, and developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (sometimes referred to as stations) dedicated to performing various tasks associated with pre- and post-lithography processing. There typically are both wet and dry processing chambers within track lithography tools. Wet chambers typically include coat and/or develop bowls, while dry chambers typically include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool, and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that every substrate processed within the track lithography tool for a particular application has the same “wafer history.” A substrate's wafer history is generally monitored and controlled by process engineers to ensure that all of the device fabrication processing variables that may later affect a device's performance are controlled, so that all substrates in the same batch are always processed the same way.

A component of the “wafer history” is the thickness, uniformity, repeatability, and other characteristics of the photolithography chemistry, which includes, without limitation, photoresist, developer, and solvents. Generally, during photolithography processes, a substrate, for example a semiconductor wafer, is rotated on a spin chuck at predetermined speeds while liquids and gases such as solvents, photoresist (resist), developer, and the like are dispensed onto the surface of the substrate. Typically, the wafer history will depend on the process parameters associated with the photolithography process.

As an example, hexamethyldisilazane (HMDS) vapor is used to improve the adhesion of photoresist to a wafer. The HMDS vapor reacts with the wafer forming a strong bond to the surface. Free bonds are left which readily react with the photoresist, enhancing the photoresist adhesion. HMDS vapor is commonly delivered to a photolithography track tool using a bubbler. This delivery method requires a large volume of photolithography chemical to be heated, is difficult to control, has limited flexibility and delivery rate, and is prone to many defects due to liquid particles. Therefore, it is desirable to control the delivery of HMDS vapor in a photolithography track tool. Present systems do not provide the level of control desirable for current and future track lithography HMDS vapor delivery tools. Therefore, there is a need in the art for improved methods and apparatus for delivering HMDS vapor in a photolithography system.

### SUMMARY OF THE INVENTION

Systems and methods in accordance with embodiments of the present invention provide for dispensing a flow of photolithography chemical vapor into a chamber. A buffer vessel and a vapor tube in a track tool are configured as a diffusion vaporizer to deliver a flow of photolithography chemical vapor to the chamber for coating a wafer. Pressure in the buffer vessel is equalized to eliminate negative pressure in the buffer vessel. The size of the buffer vessel is selected such that a volume of photolithography chemical vapor that is sufficient to coat an entire lot of wafers is provided to the chamber when there is no longer any photolithography chemical in a source bottle.

In one embodiment, a flow of photolithography chemical is directed into a buffer vessel. A pressurized flow of carrier gas is applied to a vapor tube. The pressure in the buffer vessel is equalized based on the pressurized flow of carrier gas applied to the vapor tube. A flow of liquid photolithography chemical is directed out of the buffer vessel and into the vapor tube. The photolithography chemical is vaporized in the vapor tube. A flow of the vaporized photolithography chemical is directed from the vapor tube to the chamber. A wafer in the chamber is coated with the vaporized photolithography chemical.

In another embodiment, a system for dispensing a flow of photolithography chemical vapor into a chamber includes a chemical source, a buffer vessel, a vapor tube, a carrier gas source, a pressure source, and a chamber. The chemical source supplies liquid photolithography chemical to the buffer vessel. The buffer vessel provides the liquid photolithography chemical to the vapor tube. The carrier gas source applies a pressurized flow of carrier gas to the vapor tube. The carrier gas vaporizes the liquid photolithography chemical in the vapor tube. The pressure source applies pressure to the buffer vessel such that the pressure in the buffer vessel is equalized. The pressure applied to the buffer vessel is associated with the pressure of the carrier gas applied to the vapor tube. The chamber receives the vaporized photolithography chemical from the vapor tube for coating a wafer positioned in the chamber.

In another embodiment, a computer program product includes computer program code for dispensing a flow of HMDS vapor into a chamber. The computer program code directs a flow of liquid HMDS into a buffer vessel. A pressurized flow of carrier gas is applied to a vapor tube. The pressure in the buffer vessel is equalized based on the pressurized flow of carrier gas applied to the vapor tube. A flow of liquid HMDS is directed out of the buffer vessel and into the vapor tube. The HMDS is vaporized in the vapor tube. A flow of the HMDS vapor is directed from the vapor tube to the chamber.

Other embodiments will be obvious to one of ordinary skill in the art in light of the description and figures contained herein.

### BRIEF DESCRIPTION OF THE DRAWINGS

Various embodiments in accordance with the present invention will be described with reference to the drawings, in which:

FIG. 1 is a simplified plan view of an embodiment of a track lithography tool according to an embodiment of the present invention;

FIG. 2 illustrates a photolithography chemical vapor dispense apparatus that can be used in accordance with one embodiment of the present invention;

FIG. 3 illustrates a photolithography chemical vapor dispense apparatus that can be used in accordance with another embodiment of the present invention; and

FIG. 4 illustrates steps of a method that can be used in accordance with one embodiment of the present invention.

### DETAILED DESCRIPTION OF SPECIFIC EMBODIMENTS

Systems and methods in accordance with various embodiments of the present invention overcome the afore-mentioned and other deficiencies in existing dispense systems by providing a buffer vessel and a vapor tube that are configured to behave as a diffusion vaporizer to deliver photolithography chemical vapor in a track tool. Pressure in the buffer vessel is equalized to prevent negative pressure in the buffer vessel. The size of the buffer vessel is selected such that a volume of the photolithography chemical vapor provided to a chamber is sufficient to coat an entire lot of wafers when there is no longer any photolithography chemical in a source bottle.

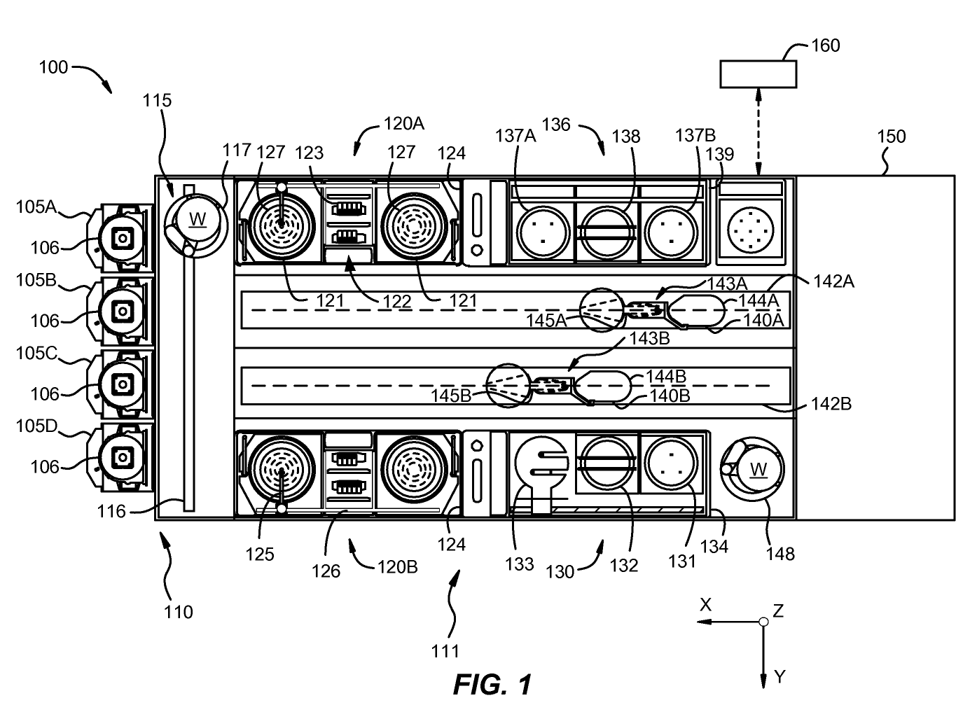

FIG. 1 is a plan view of an embodiment of a track lithography tool 100 in which the embodiments of the present invention may be used. As illustrated in FIG. 1, track lithography tool 100 contains a front end module 110 (sometimes referred to as a factory interface or FI) and a process module 111. In other embodiments, the track lithography tool 100 includes a rear module (not shown), which is sometimes referred to as a scanner interface. Front end module 110 generally contains one or more pod assemblies or FOUPS (e.g., items 105A-D) and a front end robot assembly 115 including a horizontal motion assembly 116 and a front end robot 117. The front end module 110 may also include front end processing racks (not shown). The one or more pod assemblies 105A-D are generally adapted to accept one or more cassettes 106 that may contain one or more substrates or wafers, “W,” that are to be processed in track lithography tool 100. The front end module 110 may also contain one or more pass-through positions (not shown) to link the front end module 110 and the process module 111.

Process module 111 generally contains a number of processing racks 120A, 120B, 130, and 136. As illustrated in FIG. 1, processing racks 120A and 120B each include a coater/developer module with shared dispense 124. A coater/developer module with shared dispense 124 includes two coat bowls 121 positioned on opposing sides of a shared dispense bank 122, which contains a number of nozzles 123 providing processing fluids (e.g., bottom anti-reflection coating (BARC) liquid, resist, developer, HDMS vapor, and the like) to a wafer mounted on a substrate support 127 located in the coat bowl 121. In the embodiment illustrated in FIG. 1, a dispense arm 125 sliding along a track 126 is able to pick up a nozzle 123 from the shared dispense bank 122 and position the selected nozzle over the wafer for dispense operations. Of course, coat bowls with dedicated dispense banks are provided in alternative embodiments.

Processing rack 130 includes an integrated thermal unit 134 including a bake plate 131, a chill plate 132, and a shuttle 133. The bake plate 131 and the chill plate 132 are utilized in heat treatment operations including post exposure bake (PEB), post-resist bake, and the like. In some embodiments, the shuttle 133, which moves wafers in the x-direction between the bake plate 131 and the chill plate 132, is chilled to provide for initial cooling of a wafer after removal from the bake plate 131 and prior to placement on the chill plate 132. Moreover, in other embodiments, the shuttle 133 is adapted to move in the z-direction, enabling the use of bake and chill plates at different z-heights. Processing rack 136 includes an integrated bake and chill unit 139, with two bake plates 137A and 137B served by a single chill plate 138.

One or more robot assemblies (robots) 140 are adapted to access the front-end module 110, the various processing modules or chambers retained in the processing racks 120A, 120B, 130, and 136, and the scanner 150. By transferring substrates between these various components, a desired processing sequence can be performed on the substrates. The two robots 140 illustrated in FIG. 1 are configured in a parallel processing configuration and travel in the x-direction along horizontal motion assembly 142. Utilizing a mast structure (not shown), the robots 140 are also adapted to move in a vertical (z-direction) and horizontal directions, i.e., transfer direction (x-direction) and a direction orthogonal to the transfer direction (y-direction). Utilizing one or more of these three directional motion capabilities, robots 140 are able to place wafers in and transfer wafers between the various processing chambers retained in the processing racks that are aligned along the transfer direction.

Referring to FIG. 1, the first robot assembly 140A and the second robot assembly 140B are adapted to transfer substrates to the various processing chambers contained in the processing racks 120A, 120B, 130, and 136. In one embodiment, to perform the process of transferring substrates in the track lithography tool 100, robot assembly 140A and robot assembly 140B are similarly configured and include at least one horizontal motion assembly 142, a vertical motion assembly 144, and a robot hardware assembly 143 supporting a robot blade 145. Robot assemblies 140 are in communication with a system controller 160. In the embodiment illustrated in FIG. 1, a rear robot assembly 148 is also provided.

The scanner 150, which may be purchased from Canon USA, Inc. of San Jose, Calif., Nikon Precision Inc. of Belmont, Calif., or ASML US, Inc. of Tempe Ariz., is a lithographic projection apparatus used, for example, in the manufacture of integrated circuits (ICs). The scanner 150 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 120A, 120B, 130, and 136 contain multiple processing modules in a vertically stacked arrangement. That is, each of the processing racks may contain multiple stacked coater/developer modules with shared dispense 124, multiple stacked integrated thermal units 134, multiple stacked integrated bake and chill units 139, or other modules that are adapted to perform the various processing steps required of a track photolithography tool. As examples, coater/developer modules with shared dispense 124 may be used to deposit a bottom antireflective coating (BARC) and/or deposit and/or develop photoresist layers. Integrated thermal units 134 and integrated bake and chill units 139 may perform bake and chill operations associated with hardening BARC and/or photoresist layers after application or exposure.

In one embodiment, a system controller 160 is used to control all of the components and processes performed in the cluster tool 100. The controller 160 is generally adapted to communicate with the scanner 150, monitor and control aspects of the processes performed in the cluster tool 100, and is adapted to control all aspects of the complete substrate processing sequence. The controller 140, which is typically a microprocessor-based controller, is configured to receive inputs from a user and/or various sensors in one of the processing chambers and appropriately control the processing chamber components in accordance with the various inputs and software instructions retained in the controller's memory. The controller 140 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 140 determines which tasks are performable in the processing chamber(s). Preferably, the program is software readable by the controller 160 and includes instructions to monitor and control the process based on defined rules and input data.

It is to be understood that embodiments of the invention are not limited to use with a track lithography tool such as that depicted in FIG. 1. Instead, embodiments of the invention may be used in any track lithography tool including the many different tool configurations described in U.S. patent application Ser. No. 11/315,984, entitled “Cartesian Robot Cluster Tool Architecture” filed on Dec. 22, 2005, which is hereby incorporated by reference for all purposes and including configurations not described in the above referenced application.

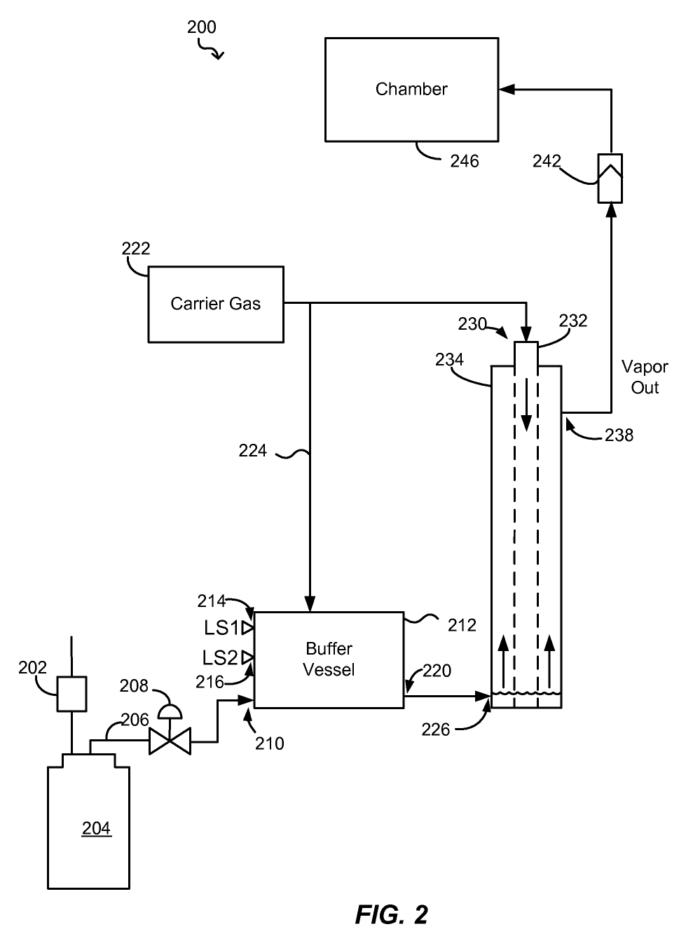

FIG. 2 shows a simplified schematic illustration of a photolithography chemical vapor dispense apparatus 200 in accordance with one embodiment. Pressure in the buffer vessel is equalized to prevent negative pressure in the buffer vessel. The size of the buffer vessel insures that a sufficient volume of the photolithography chemical vapor is provided to a chamber to coat an entire lot of wafers when a photolithography chemical source is empty.

In the system of FIG. 2, a pressure valve 202 used to apply a pressurized flow of gas is coupled to a chemical source bottle 204 containing liquid photolithography chemical (e.g. HMDS) to be dispensed into a chamber 246 as a vapor. The output line from the source bottle 204 is coupled to a flow control valve 208 in order to regulate the flow of the photolithography chemical in a fluid line 206. A buffer vessel 212 for receiving and temporarily storing the liquid photolithography chemical includes an input port 210, coupled to the fluid line 206, and an output port 220.

The buffer vessel 212 also includes level sensor LS1 (214) and level sensor LS2 (216) for regulating the volume of liquid photolithography chemical present in the buffer vessel 212. The level sensors 214, 216 are activated when a volume of liquid photolithography chemical in the buffer vessel 212 surpasses the level indicated by the corresponding level sensors 214, 216. In one embodiment, the level sensor LS1 214 operates in conjunction with the flow control valve 208 to regulate the volume of liquid photolithography chemical in the buffer vessel 212. For example, when the level sensor LS1 214 is activated, the flow control valve 208 is closed because a sufficient volume of liquid photolithography chemical is present in the buffer vessel 212. When the level sensor LS1 214 is not activated, the flow control valve 208 is opened for a set time period to allow a volume of liquid photolithography chemical to flow into the buffer vessel 212. If the level sensor LS1 214 is not activated after the time period has elapsed, then the chemical source bottle 204 is empty.

The size of the buffer vessel 212 is selected such that a sufficient volume of photolithography chemical vapor is delivered to the chamber 246 to coat an entire lot of wafers (e.g. 25 wafers) when there is no longer any photolithography chemical in the source bottle 204. In one embodiment, the level sensor LS2 216 is activated when there is a sufficient amount of photolithography chemical in the buffer vessel 212 to coat an entire lot of wafers present in the chamber 246. In one embodiment, the size of the buffer vessel 212 is selected to be in the range of 10-30 ml. Of course, the particular volume will depend on the particular application. One of ordinary skill in the art would recognize many variations, modifications, and alternatives.

A carrier gas source 222 provides carrier gas, such as nitrogen (N₂), to a vapor tube 230. A pressure equalization line 224 is provided between the carrier gas source 222 and the buffer vessel 212 such that the pressure in the buffer vessel 212 is equalized. The equalized pressure insures that negative pressure is not applied to the buffer vessel 212. The liquid photolithography chemical exits the output port 220 of the buffer vessel 212 and enters the vapor tube 230 through an input port 226. The liquid photolithography chemical accumulates in a lower portion of the vapor tube 230.

The vapor tube 230 is concentric and includes an inner column 232 and an outer column 234. In one embodiment, the wall between the inner column 232 and the outer column 234 is porous. The carrier gas is provided to the inner column 232 of the vapor tube 230. The carrier gas moves down the vapor tube 230 and reacts with the liquid photolithography chemical causing the chemical to vaporize. Thus, the buffer vessel 212 and the vapor tube 230 are configured to behave as a diffusion vaporizer. The photolithography chemical vapor exits the vapor tube 230 via an output port 238.

A shut off valve 242 may be coupled to the fluid line running from the output port 238 of the vapor tube 230. The photolithography chemical vapor is delivered to the chamber 246 from the shut off valve 242. The chemical vapor may then coat wafers that are positioned in the chamber 246.

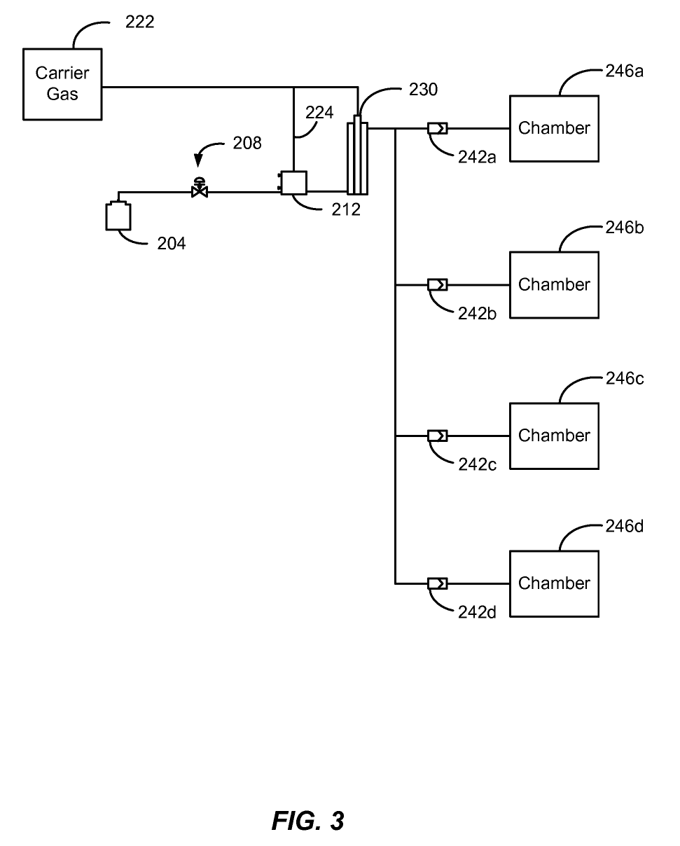

FIG. 3 is a simplified schematic illustration of a photolithography chemical vapor dispense apparatus according to another embodiment of the present invention. A source bottle 204 is connected to a flow control valve 208. The flow control valve 208 is utilized to control the flow of liquid photolithography chemical from the source bottle 204 to a buffer vessel 212. In some embodiments, the flow control valve 208 is operated under computer control to deliver predetermined amounts of the photolithography chemical to the buffer vessel 212.

The buffer vessel 212 provides a sufficient volume of the liquid photolithography chemical to a vapor tube 230 such that an entire lot of wafers in chambers 246a, 246b, 246c, and 246d may be coated with photolithography chemical vapor even when the source bottle 204 is empty. A carrier gas source 222 provides carrier gas (e.g., nitrogen) to the vapor tube 230. A pressure equalization line 224 between the carrier gas source 222 and the buffer vessel 212 insures that the pressure in the buffer vessel 212 is equalized. The equalized pressure prevents negative pressure from being applied to the buffer vessel 212.

The liquid photolithography chemical is vaporized in the vapor tube 230 when the liquid chemical reacts with the carrier gas. The photolithography chemical vapor exits the vapor tube 230 and is delivered to the chambers 246a-246d via shut off valves 242a, 242b, 242c, and 242d. The wafers in the chambers 246a-246d may then be coated with the photolithography chemical vapor.

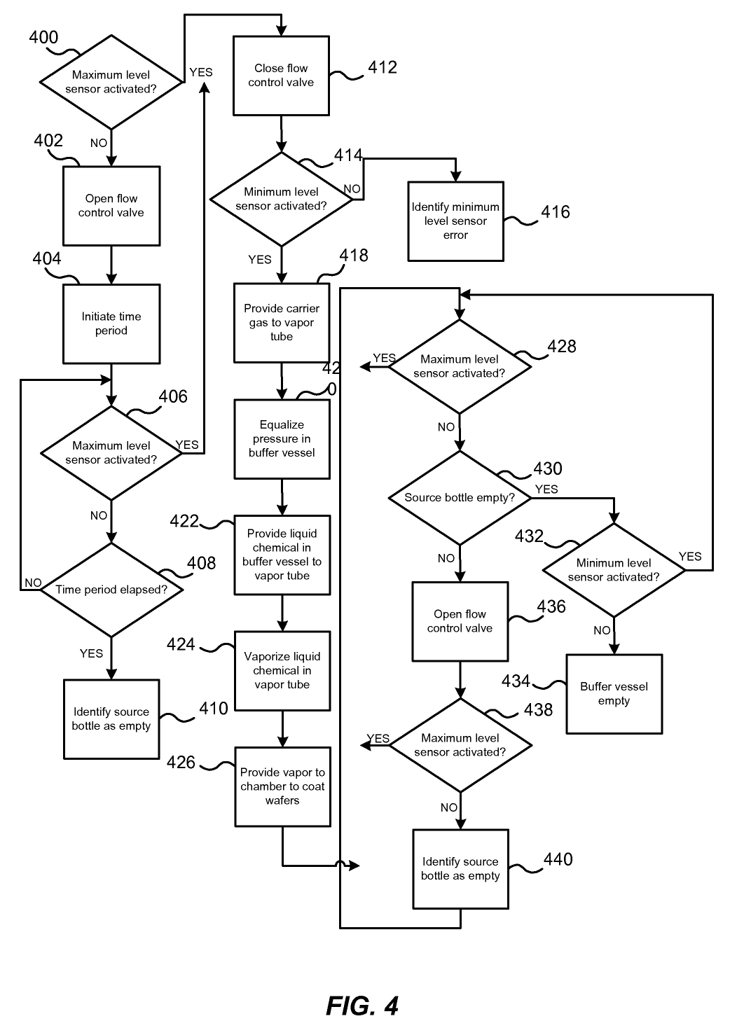

FIG. 4 is a simplified flowchart illustrating a method of operating an integrated photolithography chemical vapor dispense apparatus according to an embodiment of the present invention. At operation 400, a determination is made whether a maximum level sensor in the buffer vessel is activated. The maximum level sensor is activated when a volume of liquid photolithography chemical in the buffer vessel exceeds the level detected by the maximum level sensor. If the maximum level sensor is activated, the flow control valve is closed at operation 412 to halt the flow of liquid photolithography chemical into the buffer vessel. If the maximum level sensor is not activated, the flow control valve is opened at operation 402 to allow liquid photolithography chemical to flow into the buffer vessel from a source bottle. A time period is initiated at operation 404. The time period is selected such that the maximum level sensor is activated when photolithography chemical flows into the buffer vessel for the entire time period.

At operation 406, a determination is made whether the maximum level sensor in the buffer vessel is activated. The maximum level sensor would activate if photolithography chemical flowing into the buffer vessel surpasses the level detectable by the maximum level sensor. If the maximum level sensor is activated, the flow control valve is closed at operation 412 to halt the flow of liquid photolithography chemical into the buffer vessel. If the maximum level sensor is not activated, a determination is made at operation 408 whether the time period has elapsed. If the time period has not elapsed, processing returns to operation 406 to determine if the maximum level sensor is activated. If the time period has elapsed, then the photolithography chemical source bottle is identified as empty at operation 410.

At operation 414, a determination is made whether a minimum level sensor is activated. The minimum level sensor is activated when a volume of liquid photolithography chemical in the buffer vessel exceeds the level detected by the minimum level sensor. If the minimum level sensor is not activated, the minimum level sensor is identified as not operating properly at operation 416. If the minimum level sensor is activated, then there is a sufficient volume of photolithography chemical in the buffer vessel to coat an entire lot of wafers in a chamber.

At operation 418, a carrier gas source provides carrier gas to a vapor tube. In one embodiment, the carrier gas is nitrogen. A pressure equalization line between the carrier gas source and the buffer vessel equalizes the pressure in the buffer vessel at operation 420. The equalized pressure in the buffer vessel prevents negative pressure from being applied to the buffer vessel. The liquid photolithography chemical exits the buffer vessel and enters the vapor tube at operation 422. The carrier gas in the vapor tube causes the liquid photolithography chemical to vaporize at operation 424. The photolithography chemical vapor is then provided to the chamber to coat the wafers positioned in the chamber at operation 426.

At operation 428, a determination is made whether the maximum level sensor is activated. Processing is suspended until the maximum level sensor is not activated. At operation 430, a determination is made whether the photolithography chemical source bottle is empty. The source bottle may have been identified as empty at operation 410. If the source bottle is empty, a determination is made at operation 432 whether the minimum level sensor is activated. If the minimum level sensor is activated, then there is a sufficient volume of photolithography chemical in the buffer vessel to coat an entire lot of wafers in the chamber and processing continues at operation 428. If the minimum level sensor is not activated, the buffer vessel is identified as empty at operation 434.

If the source bottle is not empty, processing continues to operation 436 where the flow control valve is opened to allow liquid photolithography chemical to flow from the source bottle into the buffer vessel. A determination is made at operation 438 whether the maximum level sensor is activated. Processing is suspended until the maximum level sensor is not activated. If the maximum level sensor is not activated, the source bottle is identified as empty at operation 440.

It should be appreciated that the specific steps illustrated in FIG. 4 provide a particular method of operating an integrated photolithography chemical vapor dispense apparatus according to an embodiment of the present invention. Other sequence of steps may also be performed according to alternative embodiments. For example, alternative embodiments of the present invention may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular applications. One of ordinary skill in the art would recognize many variations, modifications, and alternatives.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A method of dispensing a flow of photolithography chemical vapor into a chamber, comprising:
directing a flow of liquid photolithography chemical into a buffer vessel;
applying a pressurized flow of carrier gas to a vapor tube;
equalizing the pressure in the buffer vessel based on the pressurized flow of carrier gas applied to the vapor tube;
directing a flow of liquid photolithography chemical out of the buffer vessel and into the vapor tube;
vaporizing the photolithography chemical in the vapor tube;
directing a flow of the vaporized photolithography chemical from the vapor tube to the chamber; and
coating a wafer in the chamber with the vaporized photolithography chemical.

2. The method of claim 1 wherein the photolithography chemical comprises hexamethyldisilazane (HMDS).

3. The method of claim 1 wherein the carrier gas comprises nitrogen.

4. The method of claim 1 wherein the buffer vessel and the vapor tube are configured to be a diffusion vaporizer.

5. The method of claim 1 further comprising regulating the flow of liquid photolithography chemical into the buffer vessel such that a sufficient volume of vaporized photolithography chemical is provided to the chamber to coat an entire lot of wafers.

6. The method of claim 1 wherein equalizing the pressure in the buffer vessel prevents a negative pressure being applied to the buffer vessel.

7. The method of claim 1 wherein equalizing the pressure in the buffer vessel further comprises applying a pressure to the buffer vessel that is substantially the same as the pressure of the flow of the carrier gas that is applied to the vapor tube.

8. The method of claim 1 wherein vaporizing the photolithography chemical further comprises vaporizing the photolithography chemical when the liquid photolithography chemical reacts with the carrier gas.

9. The method of claim 1 further comprising applying a pressurized flow of fluid to a chemical source bottle in order to direct the photolithography chemical out of the chemical source bottle and into the buffer vessel.

10. A system for dispensing a flow of photolithography chemical vapor into a chamber, comprising:
a chemical source for supplying a flow of liquid photolithography chemical;
a buffer vessel configured to receive the flow of liquid photolithography chemical from the chemical source;
a vapor tube operable to receive a flow of liquid photolithography chemical from the buffer vessel;
a carrier gas source operable to apply a pressurized flow of carrier gas to the vapor tube, wherein the carrier gas vaporizes the liquid photolithography chemical in the vapor tube;
a pressure source operable to apply pressure to the buffer vessel such that the pressure in the buffer vessel is equalized, wherein the pressure applied to the buffer vessel is associated with the pressure of the carrier gas applied to the vapor tube; and
a chamber operable to receive a flow of the vaporized photolithography chemical from the vapor tube for coating a wafer positioned in the chamber.

11. The system of claim 10 wherein the size of the buffer vessel provides a sufficient volume of photolithography chemical to the vapor tube such that an entire lot of wafers is coated with the vaporized photolithography chemical in the chamber.

12. The system of claim 10 wherein the photolithography chemical comprises HMDS.

13. The system of claim 10 wherein the carrier gas comprises nitrogen.

14. The system of claim 10 wherein the buffer vessel and the vapor tube are configured to be a diffusion vaporizer.

15. The system of claim 10 wherein the pressure applied to the buffer vessel prevents a negative pressure from being applied to the buffer vessel.

16. The system of claim 10 wherein the pressure applied to the buffer vessel is substantially the same as the pressure of the flow of the carrier gas that is applied to the vapor tube.

17. The system of claim 10 further comprising an additional pressure source operable to apply a pressurized flow of fluid to the chemical source in order to direct the liquid photolithography chemical out of the chemical source and into the buffer vessel.

18. A computer program product stored on a computer-readable storage medium for dispensing a flow of HMDS vapor into a chamber, the computer program product comprising:
computer program code for directing a flow of liquid HMDS into a buffer vessel;
computer program code for applying a pressurized flow of carrier gas to a vapor tube;
computer program code for equalizing the pressure in the buffer vessel based on the pressurized flow of carrier gas applied to the vapor tube;
computer program code for directing a flow of liquid HMDS out of the buffer vessel and into the vapor tube;
computer program code for vaporizing the HMDS in the vapor tube; and
computer program code for directing a flow of the HMDS vapor from the vapor tube to the chamber.

19. The computer program product of claim 18 further comprising computer program code for coating a wafer in the chamber with the HMDS vapor.

20. The computer program product of claim 18 further comprising computer program code for regulating the flow of liquid photolithography chemical into the buffer vessel such that a sufficient volume of vaporized photolithography chemical is provided to the chamber to coat an entire lot of wafers.
